(19) United States
(12) Patent Application Publication
(10) Pub. No.: US 2017/0223839 A1
(43) Pub. Date: Aug. 3, 2017

(54) PRINTED CIRCUIT BOARD WITH COMPARTMENTAL SHIELDS FOR ELECTRONIC COMPONENTS AND METHODS OF FABRICATING THE SAME

(71) Applicant: Avago Technologies General IP (Singapore) Pte. Ltd, Singapore (SG)

(72) Inventors: Padam Jain, Castro Valley, CA (US); Sarah Haney, San Jose, CA (US); Ashish Alawani, San Jose, CA (US)

(21) Appl. No.: 15/009,532

(22) Filed: Jan. 28, 2016

(51) Int. Cl. H05K 3/18; H05K 3/28; H05K 3/30; H05K 3/00

(52) U.S. Cl. CPC H05K 3/181; H05K 3/002; H05K 3/0026; H05K 3/0023; H05K 3/188; H05K 3/288; H05K 3/306

(57) ABSTRACT

A method is provided for fabricating an electromagnetic shield for an electronic component on a PCB. The method includes providing a patterned metal layer; laminating the patterned metal layer with a second dielectric layer; forming a cavity in the second dielectric layer; applying a dry film resist over the second dielectric layer and the cavity; stripping the dry film resist from the second dielectric layer and portions of the cavity adjacent the cavity side walls; depositing a seed layer and metal over the second dielectric layer and the dry film resist; etching the preplating layer and the seed layer from top surfaces of a remainder of the dry film resist and the second dielectric layer; and stripping the remainder of the dry film resist, thereby exposing the preplating layer on the side walls of the cavity to provide the electromagnetic shield.

### BACKGROUND

Conventionally, electronic components for electric devices are combined in solid state circuit packages, and may be covered with external shields to form discrete shielded packages, referred to as “modules.” There is a continuous focus on miniaturization of electronic devices for various applications, which leads to increased functional integration on solid state modules.

Decreasing distances between various electronic components in a module leads to electromagnetic interference (EMI) among these electronic components, causing performance degradation. The external shields are generally shield layers that cover the top and sidewalls of the modules, and provide protection against externally generated electromagnetic radiation and environmental stresses, such as temperature, humidity (e.g., hermetic sealing), and physical impact, for example.

One drawback of the external shield covering the circuit package is that it provides no shielding of individual electronic components from internally generated electromagnetic radiation (“internal electromagnetic radiation”) produced by other electronic components within the circuit package, causing EMI, including capacitive and inductive coupling and other cross-talk, for example. Indeed, the external shield, in some cases, may aggravate the electromagnetic interference by reflecting the internal electromagnetic radiation back toward the electronic components within the module.

Accordingly, there is a need for enhanced shielding among and between electronic components within a module, which does not unduly restrict design freedom with regard to placement of the electronic components, size of the module and other features.

### BRIEF DESCRIPTION OF THE DRAWINGS

The illustrative embodiments are best understood from the following detailed description when read with the accompanying drawing figures. It is emphasized that the various features are not necessarily drawn to scale. In fact, the dimensions may be arbitrarily increased or decreased for clarity of discussion. Wherever applicable and practical, like reference numerals refer to like elements throughout the drawings and written description.

FIG. 1A is a top plane view of a solid state module including cavities with compartmental shields, according to a representative embodiment.

FIG. 1B is a cross-sectional view of the solid state module shown in FIG. 1A, including cavities with compartmental shields, according to a representative embodiment.

FIGS. 2A to 2M are simplified cross-sectional views showing an illustrative method of fabricating modules, including cavities with compartmental shields, according to a representative embodiment.

FIGS. 3A to 3D are simplified cross-sectional views showing an illustrative method of fabricating modules, including cavities with compartmental shields using a sputtering process, according to a representative embodiment.

### DETAILED DESCRIPTION

In the following detailed description, for purposes of explanation and not limitation, example embodiments disclosing specific details are set forth in order to provide a thorough understanding of the present teachings. However, it will be apparent to one of ordinary skill in the art having the benefit of the present disclosure that other embodiments according to the present teachings that depart from the specific details disclosed herein remain within the scope of the appended claims. Moreover, descriptions of well-known apparatuses and methods may be omitted so as to not obscure the description of the example embodiments. Such methods and apparatuses are clearly within the scope of the present teachings.

The terminology used herein is for purposes of describing particular embodiments only, and is not intended to be limiting. The defined terms are in addition to the technical, scientific, or ordinary meanings of the defined terms as commonly understood and accepted in the relevant context.

The terms “a”, “an” and “the” include both singular and plural referents, unless the context clearly dictates otherwise. Thus, for example, “a device” includes one device and plural devices. The terms “substantial” or “substantially” mean to within acceptable limits or degree. The term “approximately” means to within an acceptable limit or amount to one of ordinary skill in the art. Relative terms, such as “above,” “below,” “top,” “bottom,” “upper” and “lower” may be used to describe the various elements” relationships to one another, as illustrated in the accompanying drawings. These relative terms are intended to encompass different orientations of the device and/or elements in addition to the orientation depicted in the drawings. For example, if the device were inverted with respect to the view in the drawings, an element described as “above” another element, for example, would now be below that element. Where a first device is said to be connected or coupled to a second device, this encompasses examples where one or more intermediate devices may be employed to connect the two devices to each other. In contrast, where a first device is said to be directly connected or directly coupled to a second device, this encompasses examples where the two devices are connected together without any intervening devices other than electrical connectors (e.g., wires, bonding materials, etc.).

Compartmental shielding of individual or sets of electronic components in a solid state module (or package) minimizes EMI issues. In various representative embodiments, one or more cavities in a dielectric layer of a module are used for placing active and passive electronic components, which need to be shielded, e.g., from one another and from other source of electromagnetic radiation. Walls of each cavity may be covered with plated or sputtered metal, such as copper (Cu), silver (Ag), gold (Au), aluminum (Al), or high permeability metal alloys (permalloys), and are electrically grounded. The embodiments provide a solution by using existing equipment and materials and minimal impact to the overall substrate and assembly processing. They also provide an added benefit of the low module profile, and there is minimal impact to package real estate. The various embodiments also provide flexibility for placement of the components, where electronic components needing electromagnetic shielding are placed in shielded cavities, while other electronic components may be accommodated elsewhere, such as surface mounting.

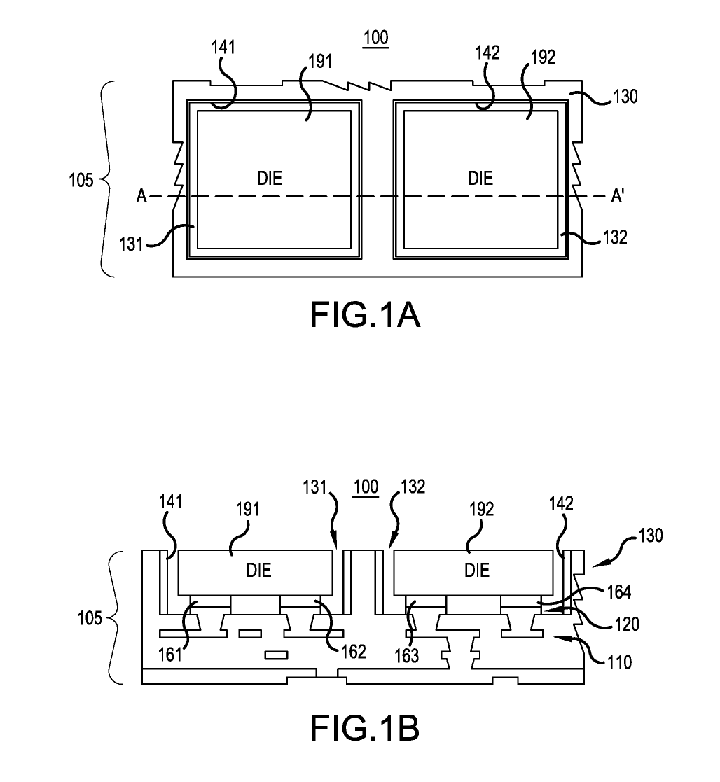

FIG. 1A is a top plane view of a solid state module including cavities with compartmental shields, and FIG. 1B is a cross-sectional view of the solid state module shown in FIG. 1A, including cavities with compartmental shields, according to a representative embodiment. FIGS. 1A and 1B depict two cavities with compartmental shields for purposes of illustration. It is understood that various embodiments and/or configurations may include more or fewer than two cavities with compartmental shields, or a combination of cavities with and without compartmental shields, without departing from the scope of the present teachings.

Referring to FIGS. 1A and 1B, solid state module 100 includes a printed circuit board (PCB) 105 having multiple layers. In the depicted example, the PCB 105 includes first dielectric layer 110, a patterned metal layer 120 formed over the first dielectric layer 110, and second dielectric layer 130 disposed over the patterned metal layer 120. The second dielectric layer 130 defines multiple cavities, shown as illustrative first cavity 131 and second cavity 132. The PCB 105 further includes first compartmental shield 141 and second compartmental shield 142, attached to the side walls of the first and second cavities 131 and 132, respectively. Each of the first and second compartmental shields 141 and 142 is formed of an electrically conductive material, and is electrically grounded. Although each of the first and second cavities 131 and 132 are shown to include first and second compartmental shields 141 and 142 covering all sidewalls, respectively, it is understood that one or both of the first and second compartmental shields 141 and 142 may cover fewer than all of the sidewalls of the first and second cavities 131 and 132, and/or may cover less than full heights of the sidewalls of the first and second cavities 131 and 132, without departing from the scope of the present teachings.

A first electronic component (e.g., first die) 191 is positioned within the first cavity 131, and is thus surrounded by the first compartmental shield 141, and a second electronic component (e.g., second die) 192 is positioned within the second cavity 132, and is thus surrounded by the second compartmental shield 142. Accordingly, each of the first and second electronic components 191 and 192 is protected from electromagnetic interference (EMI), including EMI caused by internally generated electromagnetic radiation, e.g., produced by one another, and/or caused by externally generated electromagnetic radiation, e.g., produced by neighboring modules, external power sources, and the like. The first and second electronic components 191 and 192 may be any of a variety of electronic components that may be susceptible to EMI, such as acoustic filters, flipped chip integrated circuits, wirebond dies, and other surface mounted technology (SMT) components. Examples of the acoustic filters include surface acoustic wave (SAW) resonator filters, and bulk acoustic wave (BAW) resonator filters. Examples of a flipped chip IC include power amplifiers, switches, complementary metal-oxide semiconductor (CMOS) circuits and integrated silicon-on-insulator (SOI) circuits. Of course, the number and types of first and second electronic components 191 and 192 are not limited. In comparison, a conventional PCB would have electronic components mounted to a surface, thus exposed to electromagnetic radiation or protected by shielding also arranged on the surface of the PCB (e.g., between adjacent electronic components).

The first electronic component 191 may be connected to pads 121 and 122 of the patterned layer 120 that are exposed at that bottom surface of the first cavity 131 (e.g., via solder joints 161 and 162, respectively). Likewise, the second electronic component 192 may be connected to pads 123 and 124 of the patterned layer 120 that are exposed at that bottom surface of the second cavity 132 (e.g., via solder joints 163 and 164, respectively). In an embodiment, the first and second compartmental shields 141 and 142 are electrically connected to ground to corresponding ground pads (not shown in FIGS. 1A and 1B), for example, exposed at the bottom surfaces of the first and second cavities 131 and 132, respectively, although the first and second compartmental shields 141 and 142 may be electrically grounded by other means, without departing from the scope of the present teachings.

In various embodiments, a molded compound (not shown) may be disposed over the second dielectric layer 130 and the first and second electronic components 191 and 192 positioned within the first and second cavities 131 and 132, respectively. The molded compound generally fills gaps between the first and second electronic components 191 and 192 and the first and second compartmental shields 141 and 142, respectively, attached to the side walls of the first and second cavities 131 and 132. The molded compound generally protects the first and second electronic components 191 and 192, and provides additional structural support to the module 100. In various embodiments, the molded compound hermetically seals the first and second electronic components 191 and 192. Alternatively, instead of molded compound, other resin based dielectric material(s) may be disposed over the second dielectric layer 130 and the first and second electronic components 191 and 192, for example, for continuous construction of the circuit if more layer(s) of the PCB 105 are to be added.

The first dielectric layer 110 may be formed of “prepeg” material, for example, which generally includes a base material, such as glass fabric impregnated with resin. As shown in FIG. 1B, the first dielectric layer 110 may include internal circuitry, the presence and configuration of which may vary to provide unique benefits for any particular situation or to meet application specific design requirements of various implementations, as would be apparent to one skilled in the art. The patterned metal layer 120, provided on surface of the first dielectric layer 110, may be formed of any material compatible with semiconductor processing for providing electrical circuits and/or thermal dissipation, such as copper (Cu), gold (Au), silver (Ag), or aluminum (Al), for example. The second dielectric layer 130 may likewise be for of prepreg material, for example. One or both of the first and second dielectric layers 110 and 130 may be formed of dielectric material other than prepreg, without departing from the scope of the present teachings. For example, the first and second dielectric layers 110 and 130 may be formed of any resin based dielectric material, including prepreg, film type materials and photo imagable materials.

The first and second compartmental shields 141 and 142 may be formed of the electrically conductive material that may be attached or bonded to the side walls of the first and second cavities 131 and 132, respectively. Such electrically conductive material includes copper (Cu), copper plating, silver (Ag), gold (Au), aluminum (Al), or high permeability metal alloys (permalloys), such as a MuMetal® available from Magnetic Shield Corporation, for example, although other types of conductive materials may be incorporated without departing from the scope of the present teachings. The electrically conductive material attached to the side walls of the first and second cavities 131 and 132 may have a thickness in a range of about 0.1 μm to about 20 μm, for example.

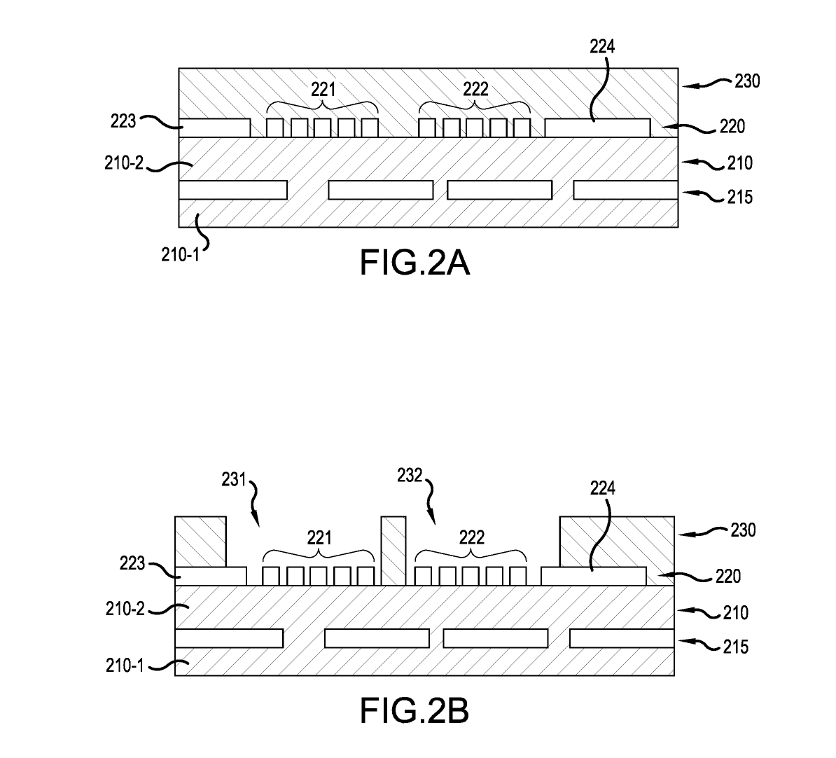

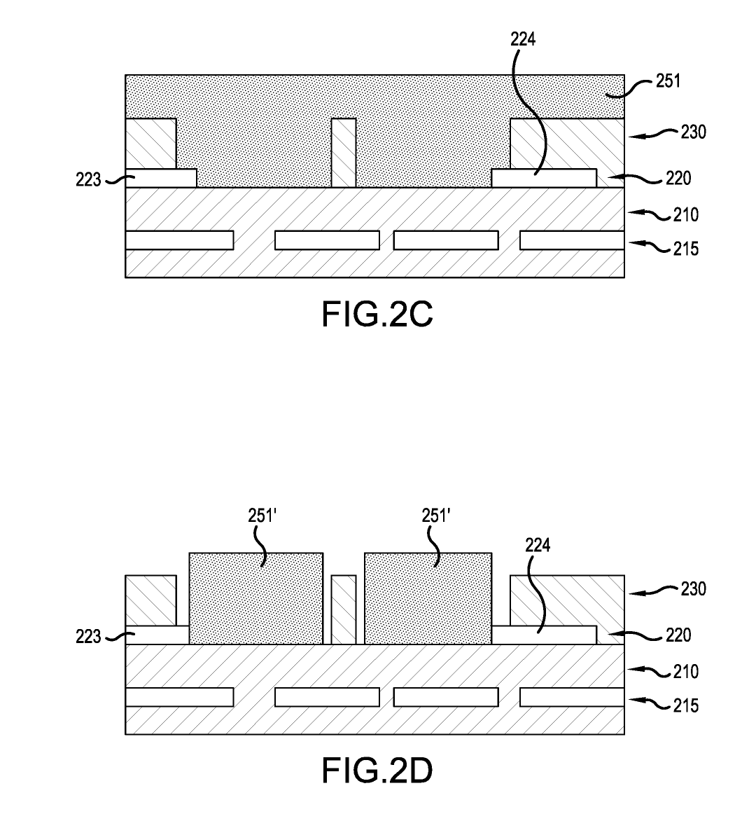

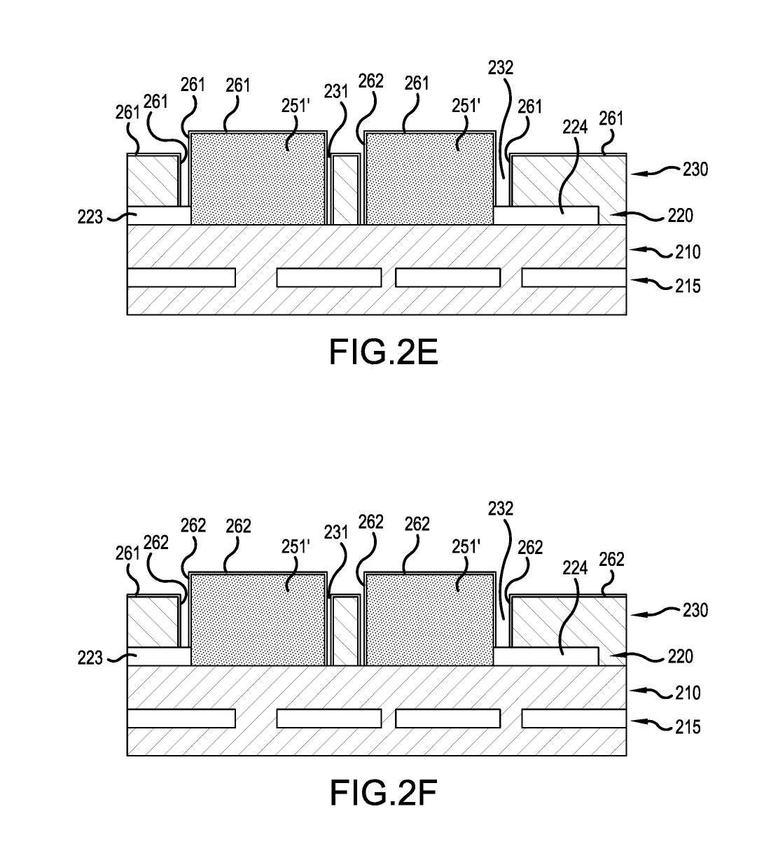

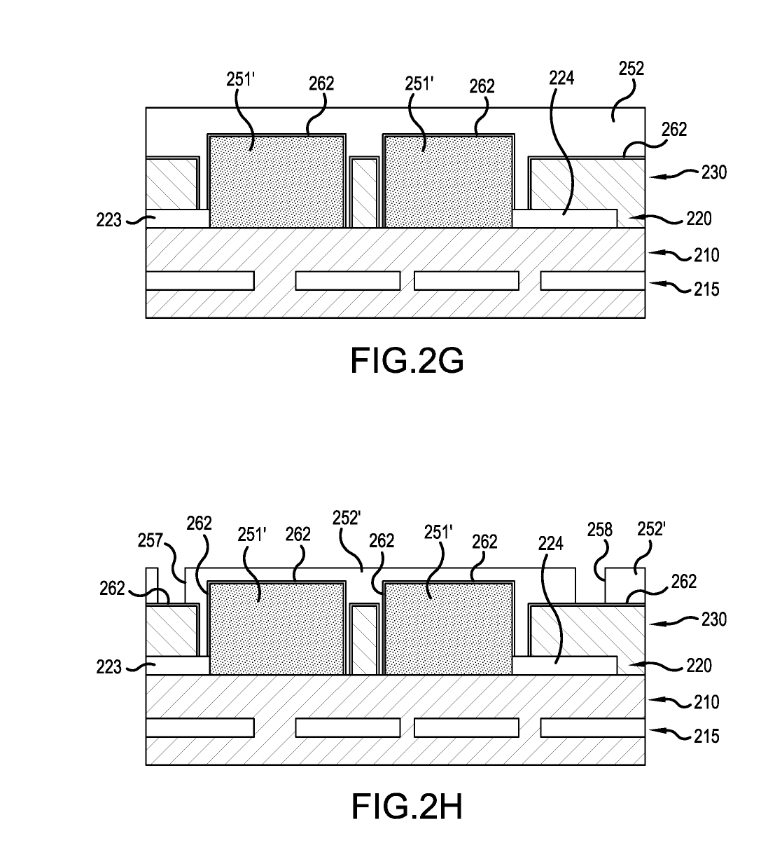

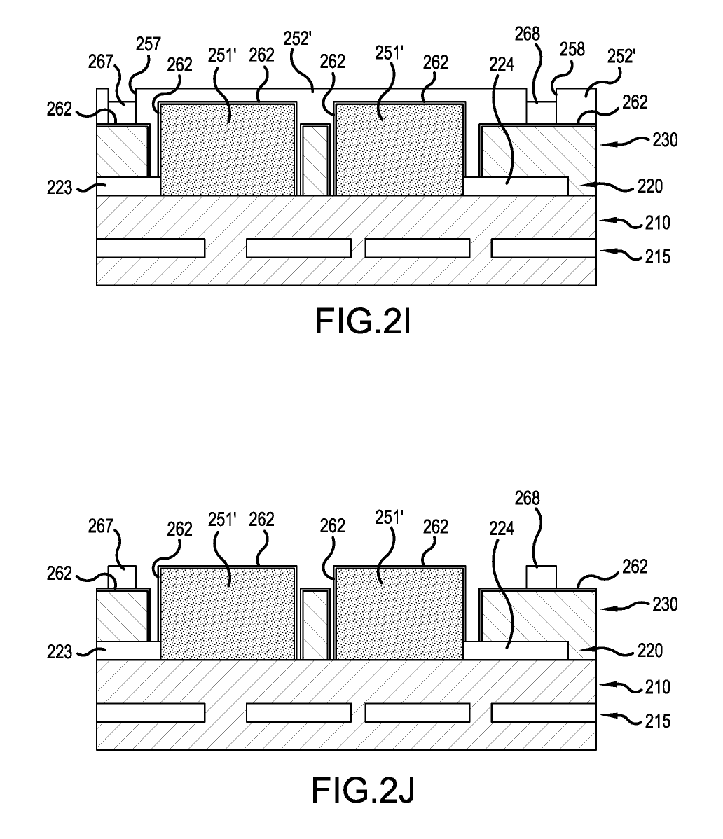

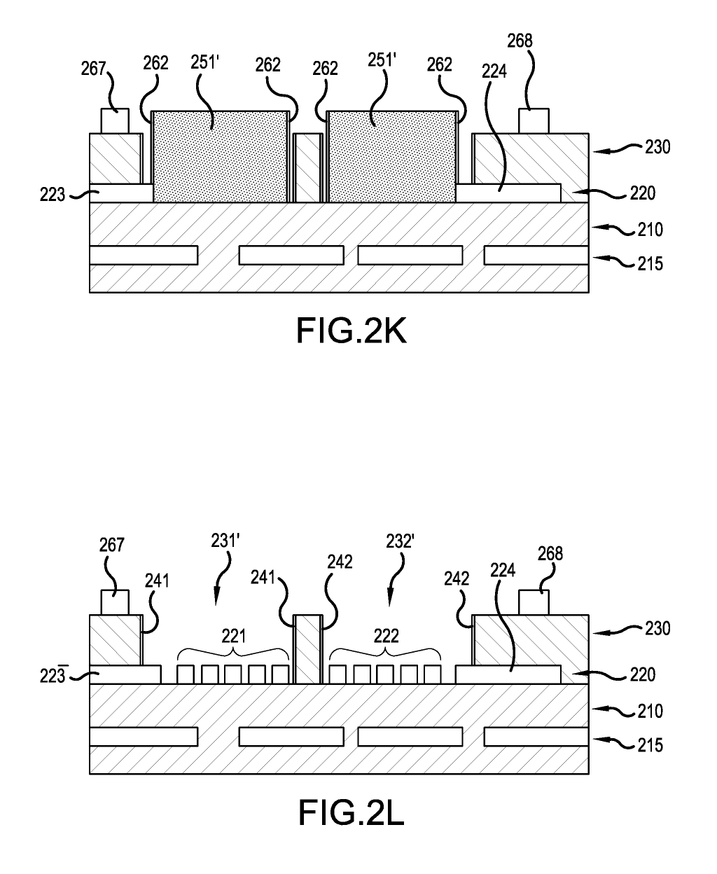

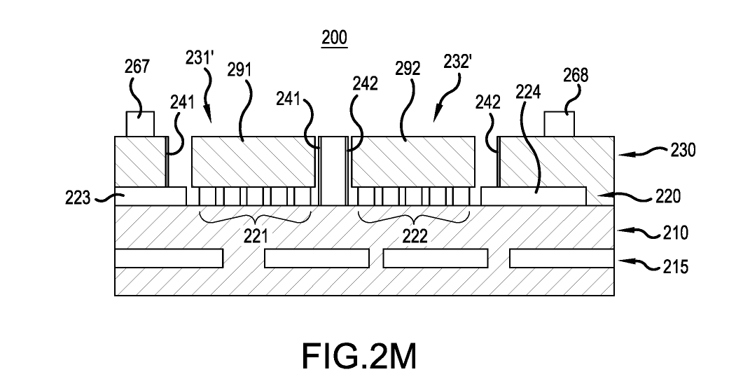

FIGS. 2A to 2M are simplified cross-sectional views showing an illustrative method of fabricating modules, including cavities with compartmental shields, according to a representative embodiment.

Referring to FIG. 2A, a partially formed PCB is provided, including a first dielectric layer 210, a patterned metal layer 220 and a second dielectric layer 230, stacked in that order. Stated differently, the patterned metal layer 220 is laminated with dielectric material of the second dielectric layer 230. Each of the first dielectric layer 210 and the second dielectric layer 230 is formed of a prepreg material, a resin-based dielectric material, or a combination of both, for example. In various embodiments, the first and second dielectric layers 210 and 230 may be formed of the same or different materials from one another. The patterned metal layer 220 is formed of an electrically conductive material, compatible with semiconductor processes, such as copper (Cu), gold (Au), silver (Ag), or aluminum (Al), for example.

In the depicted embodiment, the patterned metal layer 220 includes at least one signal pad, indicated by illustrative first and second sets of signal pads 221 and 222, and at least one ground pad, indicated by illustrative first and second ground pads 223 and 224. In the depicted example, the first dielectric layer 210 further includes an embedded circuit 215, which may be formed as a separate patterned metal layer between lower and upper first dielectric layers 210-1 and 210-2, for example. However, the embedded circuit 215 may be omitted, or other types and/or numbers of embedded circuits may be included in the first dielectric layer 210, without departing from the scope of the present teachings.

Referring to FIG. 2B, a first cavity 231 and a second cavity 232 are formed in the dielectric layer 230. The first and second cavities 231 and 232 may be formed by removing dielectric material corresponding to a volume of each of the first and second cavities 231 and 232 using a laser process or a wet etching process, for example, although other methods may be incorporated. The corresponding cavity volumes may be the same as or different from one another, depending on application specific design requirements of various implementations, as would be apparent to one skilled in the art. Each of the first and second cavities 231 and 232 extends to a top surface of the first dielectric layer 210 on which the patterned metal layer 220 is formed, thereby exposing the first and second sets of signal pad 221 and 222, as well as at least a portion of each of the first and second ground pads 223 and 224. The first and second cavities 231 and 232 have corresponding side walls. The side walls are depicted as being substantially vertical and parallel to one another for convenience of explanation, although is understood that the side walls of one or both of the first and second cavities 231 and 232 may be slanted, curved or define some other shape (symmetrical or asymmetrical), without departing from the scope of the present teachings.

As shown in FIG. 2C, a first dry film resist (DFR) 251 is applied over the second dielectric layer 230, and the first and second cavities 231 and 232. This process may be referred to as first DRF lamination. The first dry film resist 251 thereby covers to the top (or upper) surface of the second dielectric layer 230, and substantially fills each of the first and second cavities 231. A pattern (not shown) may be applied to the first dry film resist 251, and a lithography process may be performed using the pattern to remove portions of the first dry film 251, resulting in first dry film resist pattern 251′, an example of which is shown in FIG. 2D. Generally, the lithography process results in removal of portions of the first dry film resist 251 from the top surface of the second dielectric layer 230, and from within portions of each of the first and second cavities 231 and 232 to expose at least a portion of the first and second ground pads 223 and 224, respectively. For example, the lithography process removes portions the first dry film resist 251 from each of the first and second cavities 231 and 232, adjacent the corresponding side walls of the first and second cavities 231 and 232.

Referring to FIGS. 2E and 2F, electrically conductive material is applied to the surfaces of the second dielectric layer 230 and the first dry film resist pattern 251′. For example, as shown in FIG. 2E, a metal (e.g., copper (Cu)) is electrolessly deposited on the second dielectric layer 230 and the first dry film resist pattern 251′ as a seed layer 261. The seed layer 261 covers top and side surfaces of the second dielectric layer 230 and the first dry film resist pattern 251′, including within the first and second cavities 231, although the seed layer 261 covering each surface (horizontal or vertical) is not necessarily labeled, for the sake of convenience. Then, as shown in FIG. 2F, additional metal is electrolytically deposited over the seed layer 261 to provide a preplating layer 262 (e.g., Cu preplating layer), the combined seed layer 261 and preplating layer 262 (collectively indicated by reference number 262) generally increasing the thickness of metal applied to the exposed surfaces of the second dielectric layer 230 and the first dry film resist pattern 251′. Similar to the above discussion, the preplating layer 262 covers the seed layer 261 on the top and side surfaces of the second dielectric layer 230 and the first dry film resist pattern 251′, including within the first and second cavities 231, although the preplating layer 262 covering each surface (horizontal or vertical) is not necessarily labeled, for the sake of convenience.

As shown in FIG. 2G, a second dry film resist (DFR) 252 is applied over the second preplating layer 262 on the second dielectric layer 230 and the first dry film resist pattern 251′, which may be referred to as second DFR lamination. The second dry film resist 252 covers the top surfaces of the preplating layer 262 and the first dry film resist pattern 251′, and fills spaces between the first dry film resist pattern 251′ and the portions of the preplating layer 262 on the side walls of the first and second cavities 231 and 232. A pattern (not shown) may be added to the second dry film resist 252. A lithography process may be performed using the pattern, for example, to remove portions of the second dry film resist 252 over the preplating layer 262 on the second dielectric layer 230 resulting in second dry film resist pattern 252′, including first and second openings 257 and 258, as shown in FIG. 2H. The first and second openings 257 and 258 formed by the lithography process expose corresponding portions of the preplating layer 262. Metal plating (e.g., Cu plating) is applied (or electroplated) within the first and second openings 257 and 258, as shown in FIG. 2I, to form metal contacts 267 and 268. The metal plating may use the preplating layer 262 exposed at the bottom of the first and second openings 257 and 258, respectively, as a seed layer for forming the first and second metal contacts 267 and 268.

Referring to FIG. 2J, the second dry film resist pattern 252′ is removed through a stripping process, thereby exposing the preplating layer 262, as well as the first and second metal contacts 267 and 268. The stripping process may be performed using a stripping solution, for example, although other techniques for removing the second dry film resist pattern 252′ may be incorporated without departing from the scope of the present teachings. A flash etch is then performed to remove the preplating layer 262 and the underlying seed layer 261 from the top (e.g., horizontal, in the depicted orientation) surfaces of second dielectric layer 230 and the first dry film resistor pattern 251′, as shown in FIG. 2K. Due to the thickness of the first and second metal contacts 267 and 268 being larger than the relatively thin combination of the preplating layer 262 and the seed layer 261, the first and second metal contacts 267 and 268 remain in place following the flash etching (although they may lose a small amount of material on the corresponding top surfaces).

Referring to FIG. 2L, the first dry film resist pattern 251′ is removed through another stripping process, thereby exposing the first and second sets of signal pads 221 and 222, and the first and second ground pads 223 and 224 (to the extent they were not already exposed). The stripping process may be performed using a stripping solution, for example, although other techniques for removing the first dry film resist pattern 251′ may be incorporated without departing from the scope of the present teachings. The removal of the first dry film resist pattern 251′ leaves in place a first shielded cavity 231′ and a second shielded cavity 232′. In particular, the first shielded cavity 231′ comprises the initial first cavity 231 with the preplating layer 262 still adhered to the corresponding side walls to provide a first compartmental shield 241. Likewise, the second shielded cavity 232′ comprises the initial second cavity 232 with the preplating layer 262 still adhered to the corresponding side walls to provide a second compartmental shield 242. As shown, the first compartmental shield 241 is in physical and electrical contact with the first ground pad 223, and the second compartmental shield 242 is in physical and electrical contact with the second ground pad 224, thus electrically grounding both the first and second compartmental shields 241 and 242. Of course, alternative means for electrically grounding the first and second compartmental shields 241 and 242 may be provided, such as top ground or grounding through the second dielectric layer 230, without departing from the scope of the present teachings.

Referring to FIG. 2M, a first electronic component (e.g., first die) 291 is inserted into the first shielded cavity 231′, connecting to the first set of signal pads 221, and the second electronic component (e.g., second die) 292 is inserted into the second shielded cavity 232′, connecting the to the second set of signal pads 222, thus providing solid state module 200. The first electronic component 291 positioned within the first shielded cavity 231′ is surrounded by the first compartmental shield 241, and the second electronic component 292 positioned within the second shielded cavity 232′ is surrounded by the second compartmental shield 242. Accordingly, each of the first and second electronic components 291 and 292 is protected from EMI, including EMI caused by internally generated electromagnetic radiation, e.g., produced by one another, and caused by externally generated electromagnetic radiation, e.g., produced by neighboring modules, external power sources, and the like. The first and second electronic components 291 and 292 may be any of a variety of electronic components that may be susceptible to EMI, as discussed above with reference to the first and second electronic components 191 and 192 in FIGS. 1A and 1B. Again, it is understood that various embodiments and/or configurations may include more or fewer than two cavities with compartmental shields, or a combination of cavities with and without compartmental shields, without departing from the scope of the present teachings.

In the depicted example, the first electronic component 291 is physically and electrically connected to the first set of signal pads 221, and the second electronic component 292 is physically and electrically connected to the second set of signal pads 222. This enables electrical and/or thermal conductivity between each of the first and second electronic components 291 and 292 and other circuitry within the module 200 (such as the embedded circuit 215). Also, the first and second metal contacts 267 and 268 enables electrical and/or thermal conductivity with additional circuitry that may be placed on the module 200. For example, a third dielectric layer (not shown) may be formed over the second dielectric layer 230 and the first and second shielded cavities 231′ and 232′, where circuitry (not shown) contained in or on the third dielectric layer (e.g., via another patterned metal layer) is physically and/or electrically connected to at least one of the first and second metal contacts 267 and 268.

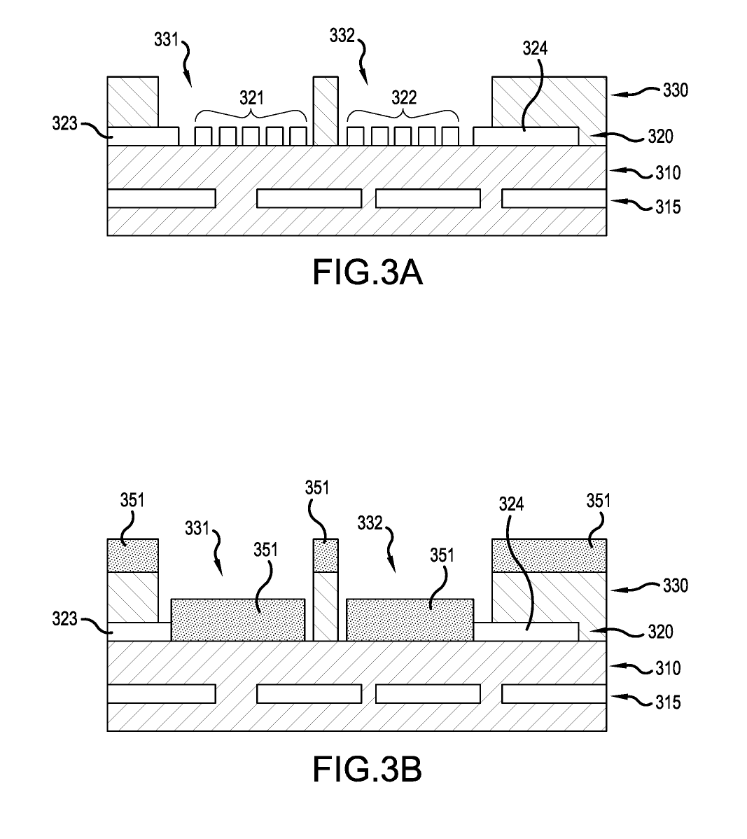

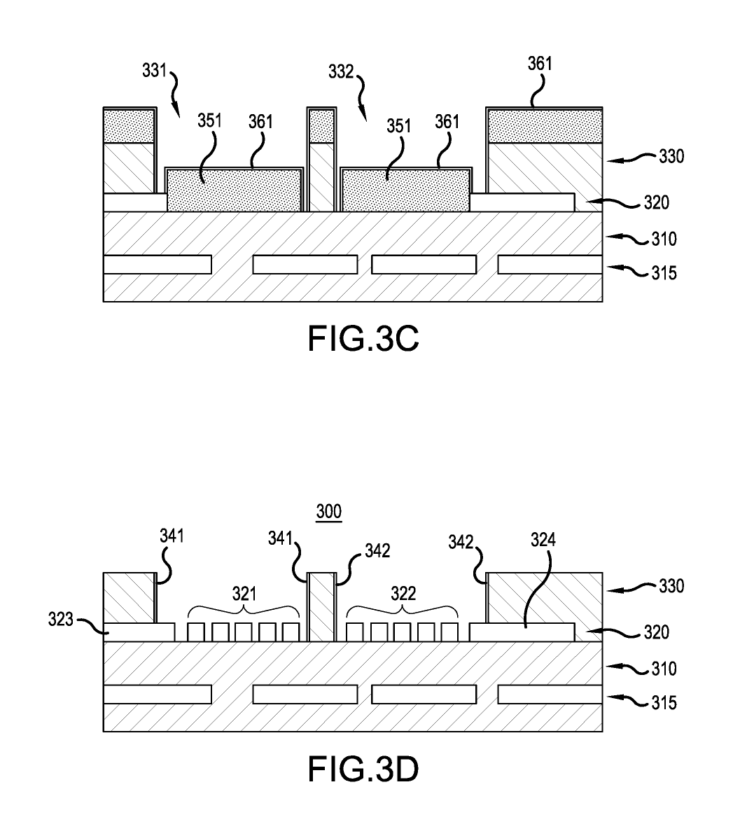

FIGS. 3A to 3D are simplified cross-sectional views showing an illustrative method of fabricating modules, including cavities with compartmental shields, using a sputtering process, according to another representative embodiment.

Referring to FIG. 3A, a partially formed PCB is provided, including a first dielectric layer 310, a patterned metal layer 320 and a second dielectric layer 330, stacked in that order, where the second dielectric layer 330 defines first and second cavities 331 and 332, which may be formed, for example, as described above with reference to first and second cavities 231 and 232 in FIGS. 2A and 2B. Each of the first dielectric layer 310 and the second dielectric layer 330 is formed of a prepreg material, a resin-based dielectric material, or a combination of both, for example. The patterned metal layer 320 is formed of an electrically conductive material, compatible with semiconductor processes, such as copper (Cu), gold (Au), silver (Ag), or aluminum (Al), for example.

In the depicted embodiment, the patterned metal layer 320 includes at least one signal pad, indicated by illustrative first and second sets of signal pads 321 and 322, and at least one ground pad, indicated by illustrative first and second ground pads 323 and 324. The first and second sets of signal pads 321 and 322, and the first and second ground pads 323 and 324, may be substantially the same as discussed above with reference to first and second sets of signal pads 221 and 222, and first and second ground pads 223 and 224, respectively. In the depicted example, the first dielectric layer 310 further includes an embedded circuit 315, which is substantially the same as the embedded circuit 215, discussed above. Accordingly, detailed descriptions of these features will not be repeated.

Referring to FIG. 3B, a dry film resist (DFR) is applied over the second dielectric layer 330, and the first and second cavities 331 and 332. The first dry film resist thereby covers to the top (or upper) surface of the second dielectric layer 330, and the bottom (or lower) surface of the first and second cavities 331 and 332. A pattern (not shown) may be added to the first dry film resist, and a lithography process performed using the pattern to remove portions of the first dry film, resulting in dry film resist pattern 351, an example of which is shown in FIG. 3B. Generally, the lithography process results in removal of portions of the dry film resist from within portions of each of the first and second cavities 331 and 332, particularly along the side walls.

As shown in FIG. 3C, an electrically conductive material is sputtered onto the dry film resist pattern 351 and any exposed portions of the dielectric layer 330, forming an electrically conductive layer 361. The electrically conductive material of the electrically conductive layer 361 may include copper (Cu), copper plating, or high permeability metal alloys (permalloys), such as a MuMetal® available from Magnetic Shield Corporation, for example, although other types of conductive materials may be incorporated without departing from the scope of the present teachings. The electrically conductive material attached to the side walls of the first and second cavities 331 and 332 may also have a thickness in a range of about 0.1 μm to about 20 μm, for example.

The dry film resist pattern 351 is stripped away as shown in FIG. 3D, leaving the electrically conductive layer 361 on the side walls of each of the first and second cavities 331 and 332. The stripping process may be performed using a standard resist stripping solution or a solvent such as acetone in combination with a spray tool and/or ultrasonic bath, for example, although other techniques for removing the dry film resist pattern 351 may be incorporated without departing from the scope of the present teachings. The removal of the dry film resist pattern 351 leaves in place a first shielded cavity 331′ and a second shielded cavity 332′. In particular, the first shielded cavity 331′ comprises the initial first cavity 331 with the sputtered electrically conductive layer 361 still adhered to the corresponding side walls to provide a first compartmental shield 341. Likewise, the second shielded cavity 332′ comprises the initial second cavity 332 with the sputtered electrically conductive layer 361 still adhered to the corresponding side walls to provide a second compartmental shield 342. As shown, the first compartmental shield 341 is in physical and electrical contact with the first ground pad 323, and the second compartmental shield 342 is in physical and electrical contact with the second ground pad 324, thus electrically grounding both the first and second compartmental shields 341 and 342. Of course, alternative means for electrically grounding the first and second compartmental shields 341 and 342 may be provided, such as top ground or grounding through the second dielectric layer 330, may be incorporated without departing from the scope of the present teachings.

As discussed above with reference to FIG. 2M, a first electronic component 291 may be inserted within the first shielded cavity 331′ and a second electronic component 292 may be inserted within the second shielded cavity 332′, connecting to the first and second sets of signal pads 321 and 322, respectively, thus providing solid state module 300. The first electronic component 291 positioned within the first shielded cavity 331′ would be surrounded by the first compartmental shield 341, and the second electronic component 292 positioned within the second shielded cavity 332′ would be surrounded by the second compartmental shield 342. Accordingly, each of the first and second electronic components 291 and 292 would be protected from EMI, including EMI caused by internally generated electromagnetic radiation, e.g., produced by one another, and caused by externally generated electromagnetic radiation, e.g., produced by neighboring modules, external power sources, and the like. Again, it is understood that various embodiments and/or configurations may include more or fewer than two cavities with compartmental shields, or a combination of cavities with and without compartmental shields, without departing from the scope of the present teachings.

The various components, structures, parameters and methods are included by way of illustration and example only and not in any limiting sense. In view of this disclosure, those skilled in the art can implement the present teachings in determining their own applications and needed components, materials, structures and equipment to implement these applications, while remaining within the scope of the appended claims.

What is claimed:

1. A method of fabricating an electromagnetic shield for an electronic component on a printed circuit board, the method comprising:
providing a patterned metal layer comprising at least one signal pad and a ground pad on a first dielectric layer comprising first dielectric material;
laminating the patterned metal layer with a second dielectric layer of second dielectric material;
forming a cavity in the second dielectric layer, extending to the first dielectric layer on which the patterned metal layer is formed, and exposing the at least one signal pad and at least a portion of the ground pad, the cavity having side walls;
applying a first dry film resist over the second dielectric layer and the cavity;
stripping the first dry film resist from a top surface of the second dielectric layer and from portions of the cavity adjacent the side walls of the cavity;
electrolessly depositing metal as a seed layer over the second dielectric layer and the dry film resist;
electrolytically depositing metal over the seed layer as a preplating layer;
etching the preplating layer and the seed layer from top surfaces of a remainder of the first dry film resist and the second dielectric layer; and
stripping the remainder of the first dry film resist, thereby exposing the preplating layer on the side walls of the cavity and the at least one signal pad and the at least a portion of the ground pad within the cavity, the exposed preplating layer on the side walls of the cavity being electrically connected to the at least a portion of the ground pad within the cavity to provide the electromagnetic shield.

2. The method of claim 1, further comprising:
inserting the electronic component into the cavity, and connecting the electronic component to the at least one signal pad, wherein the electromagnetic shield shields the electronic component from electromagnetic radiation.

3. The method of claim 1, further comprising:
applying a second dry film resist over the preplating layer before etching the preplating layer and the seed layer;
removing the second dry film resist from a portion of the preplating layer;
electroplating metal over the second dry film resist and the removed portion of the preplating layer, forming a contact; and
stripping the second dry film resist, leaving the preplating layer and the seed layer on the top surfaces of the remainder of the first dry film resist and the second dielectric layer.

4. The method of claim 1, wherein forming the cavity in the second dielectric layer comprises removing a portion of the second dielectric material corresponding to a volume of the cavity using a laser.

5. The method of claim 1, wherein forming the cavity in the second dielectric layer comprises removing a portion of the second dielectric material corresponding to a volume of the cavity using a wet etching process.

6. The method of claim 1, wherein stripping the first dry film resist comprises a lithography process.

7. The method of claim 1, wherein each of the first dielectric layer and the second dielectric comprise at least one of a prepreg material and a resin-based dielectric material.

8. The method of claim 1, wherein the electrically conductive material attached to the side walls of the cavity comprises copper.

9. The method of claim 1, wherein the electrically conductive material attached to the side walls of the cavity comprises a high permeability metal alloy.

10. The method of claim 9, wherein the high permeability metal alloy comprises a MuMetal®.

11. The method of claim 1, wherein the electrically conductive material attached to the side walls of the cavity has a thickness in a range of about 0.1 μm to about 20 μm.

12. The method of claim 2, further comprising:
depositing a molded compound over the second dielectric layer and the electronic component positioned within the cavity, the molded compound filling gaps between the electronic component and the electrically conductive material attached to the side walls of the cavity.

13. A method of fabricating an electromagnetic shield in a cavity in a printed circuit board, the cavity for housing an electronic component, the method comprising:
forming the cavity in a dielectric material of the printed circuit board, thereby exposing a ground pad and at least one signal pad for connecting the electronic component, the cavity having side walls;
applying a dry film resist over the ground pad, the at least one signal pad, and select portions of the dielectric material;
sputtering an electrically conductive material onto the dry film resist and portions of the dielectric material to which the dry film resist was not applied, forming an electrically conductive layer; and
stripping the dry film resist, leaving the electrically conductive layer on at least the side walls of the cavity, the electrically conductive layer being electrically grounded to provide the electromagnetic shield in the cavity.

14. The method of claim 13, wherein the electrically conductive material comprises one of copper or permalloy.

15. The method of claim 14, wherein each of the first dielectric layer and the second dielectric comprise at least one of a prepreg material and a resin-based dielectric material.

16. The method of claim 13, wherein the electrically conductive material comprises a MuMetal®.

17. The method of claim 13, further comprising:
inserting the electronic component into the cavity, and connecting the electronic component to the at least one signal pad, wherein the electromagnetic shield shields the electronic component from electromagnetic radiation.

18. The method of claim 17, further comprising:
depositing a molded compound over the dielectric layer and the electronic component positioned within the cavity, the molded compound filling gaps between the electronic component and the electrically conductive material attached to the side walls of the cavity.
